(19) United States
(12) Patent Application Publication
(10) Pub. No.: US 2024/0260428 A1
(43) Pub. Date: Aug. 1, 2024

(54) DISPLAY DEVICE

(71) Applicant: LG DISPLAY CO., LTD., Seoul (KR)

(72) Inventor: Sunghee Park, Goyang-si (KR)

(73) Assignee: LG DISPLAY CO., LTD., Seoul (KR)

(21) Appl. No.: 18/400,045

(22) Filed: Dec. 29, 2023

(30) Foreign Application Priority Data
Jan. 31, 2023 (KR) 10-2023-0012881

(51) Int. Cl. H10K 59/80; H10K 59/122

(52) U.S. Cl. CPC H10K 59/8792; H10K 59/122; G09G 3/3233; G09G 2300/0842; G09G 2320/0209

(57) ABSTRACT

A display device has a pixel electrode having a mirror portion extending along a side surface of an opening to act as a side surface reflection mirror of light. Thus, light loss is reduced and an amount at which light is emitted from a sub-pixel is improved. Further, color mixing between light beams from adjacent sub-pixels is reduced, thereby improving light efficiency.

### CROSS-REFERENCE TO RELATED APPLICATIONS

This application claims priority from Korean Patent Application No. 10-2023-0012881 filed on Jan. 31, 2023 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device, and more specifically, relates to a transparent display device including a light-transmissive area and a light-emissive area.

### Description of Related Art

Display devices are implemented in very diverse forms such as televisions, monitors, smart phones, tablet personal computers (PCs), laptops, and wearable devices.

An example of the display device is an organic light-emitting display device (OLED) as a self-luminous display device. The OLED is not only advantageous in terms of power consumption due to low voltage operation, but also has excellent color rendering, fast response speed, wide viewing angle, and high contrast ratio.

Recently, research has been actively conducted on a transparent display device in which a user in front of the display device may see an object or an image through the display device.

The transparent display device may include a display area where an image is displayed and a non-display area.

In this case, the display area may include a light-transmissive area capable of transmitting external light therethrough and a light-emissive area in which a pixel emits light.

### SUMMARY

When an area size of the light-transmissive area of the transparent display device is increased, light transmittance may be increased.

Moreover, when the area of the light-emissive area of the transparent display device increases, an aperture ratio increases, so that the luminance and the light efficiency may increase.

However, since the area of the light-transmissive area and the area of the light-emissive area constituting the display area are correlated and in a trade-off relationship with each other, it is difficult to increase the area of the light-transmissive area and the light-emissive area.

Similarly, since the transmittance of the transparent display device is proportional to the area of the light-transmissive area and the aperture ratio of the transparent display device proportional to the area of the light-emissive area are generally correlated in a trade-off relationship with each other, it is difficult to improve both transmittance and aperture ratio.

Accordingly, aspects of the present disclosure relate to improving both the transmittance and aperture ratio of the display device.

According to aspects of the present disclosure, display device capable is provided that improves both the transmittance and the aperture ratio via adjustment of a width in a left-right direction of a black matrix layer constituting a boundary between the light-transmissive area and the light-emissive area.

According to aspects of the present disclosure, techniques for improving light efficiency in a display device are disclosed.

According to aspects of the present disclosure, techniques for improving both the transmittance and the aperture ratio in a display device are disclosed.

according to aspects of the present disclosure, techniques for improving a flatness of a lower surface on which a pixel electrode in a display device are disposed.

Moreover, according to aspects of the present disclosure, techniques for improving visibility in a light-transmissive area in a display device are disclosed.

Purposes according to the present disclosure are not limited to the above-mentioned purposes. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display device according to an aspect of the present disclosure includes a first substrate; a pixel electrode including a non-planar reflective portion extending along a side surface of an opening disposed in a light-emissive area on the first substrate; a bank layer covering the non-planar reflective portion and exposing an upper surface of the pixel electrode to be exposed; a color filter layer disposed on the pixel electrode and spaced apart from the pixel electrode; a black matrix layer disposed to partially overlap an edge of the color filter layer; and a second substrate disposed opposite to the first substrate, wherein the color filter layer and the black matrix layer are disposed on the second substrate.

In this case, a minimum width D in a left-right direction of the black matrix layer is determined based on a following Equation 1:

$$D = B - ( x - t ) \qquad [ Equation 1 ]$$

wherein in the above Equation 1, B denotes a minimum width in the left-right direction of the black matrix layer blocking virtual light beams not totally reflected from the second substrate among virtual light beams emitted from the upper surface of the pixel electrode and then passing through the reflective portion,
wherein in the above Equation 1, x denotes a width in the left-right direction between an inner side of an upper end of the reflective portion and a first light source point positioned on the upper surface of the pixel electrode, wherein light to be blocked by the black matrix layer is emitted from the first light source point,
wherein in the above Equation 1, t denotes a width in the left-right direction between the inner side of the upper end of the reflective portion and a second light source point positioned at a boundary of the upper surface of the pixel electrode not covered with the bank layer to be exposed.

According to the aspect of the present disclosure, the reflective portion of the pixel electrode extending along the side surface of the opening may act as a reflect light incident to the non-planar portion. In some aspects, the non-planar portion may also be referred to as a mirror portion of the pixel electrode.

Accordingly, the light loss in the light-emissive area is reduced and thus, the amount of the light emitted from a sub-pixel is improved. Further, color mixing between light beams from adjacent sub-pixels is reduced, thereby improving light efficiency.

Moreover, according to aspects of the present disclosure, the bank layer formed on the pixel electrode is made of an inorganic material. Thus, the bank layer may be formed to have a smaller thickness than that when the bank layer is made of an organic material, thereby reducing the width in the left-right directions of the dead zone of the light-emissive area formed on the pixel electrode to improve light efficiency.

As the light efficiency of the display device improves, a low-power display device with reduced power consumption may be implemented.

Moreover, according to aspects of the present disclosure, with considering the total reflection angle of light emitted from the upper surface of the pixel electrode and various factors related to the reflective portion of the pixel electrode, the minimum width in the left-right direction of the black matrix layer constituting the boundary between adjacent light-emissive areas and the boundary between the light-transmissive area and the light-emissive area may be calculated.

In this way, the minimum width in the left-right directions of the black matrix layer may be calculated and then may be used to reduce the dead zone of the light-emissive area formed in the light-transmissive area and the color filter layer due to the black matrix layer. Thus, both the transmittance and the aperture ratio which are correlated in a trade-off relationship with each other may be improved.

Moreover, according to aspects of the present disclosure, the transparent clad layer serves as an etch stopper in the etching process. Thus, the surface of the pixel electrode formed on the clad layer may be modified to reduce surface roughness thereof, such that the process stability may be improved.

Moreover, according to aspects of the present disclosure, at least a partial area of each of the branched structure and the low-potential voltage contact line disposed in the light-transmissive area may be composed of a transparent clad layer. Thus, fine diffraction that may occur due to non-transparent fine patterns may be minimized, thereby improving visibility in the light-transmissive area and reducing reflectivity in the light-transmissive area.

In addition to the above effects, specific effects of the present disclosure are described together while describing specific details for carrying out the present disclosure.

Effects of the present disclosure are not limited to the effects mentioned above, and other effects not mentioned will be clearly understood by those skilled in the art from the descriptions below.

### BRIEF DESCRIPTION OF THE DRAWINGS

FIG. 1 is a plan view illustrating a light-emissive area and a light-transmissive area of a display device according to an aspect of the present disclosure.

FIG. 2 is a cross-sectional view of a light-emissive area and a light-transmissive area corresponding to one sub-pixel of a display device according to an aspect of the present disclosure.

FIG. 3 is a cross-sectional view of a light-emissive area and a light-transmissive area corresponding to one sub-pixel of a display device according to another aspect of the present disclosure.

FIGS. 4 and 5 are diagrams showing variables included in an Equation calculated to minimize a dead zone of a black matrix layer of a display device according to an aspect of the present disclosure.

FIG. 6 is a plan view of a branched structure of a display device according to an aspect of the present disclosure,

FIG. 7 is a cross-sectional view of the branched structure connected to the light-emissive area.

FIG. 8 is a plan view of a branched structure of a display device according to another aspect of the present disclosure,

FIG. 9 is a cross-sectional view of the branched structure connected to the light-emissive area.

FIG. 10 is a plan view of a low-potential voltage contact line of a display device according to an aspect of the present disclosure.

FIG. 11 is a cross-sectional view of the low-potential voltage contact line connected to the light-emissive area.

FIG. 12 is a cross-sectional view of a pad of a display device according to an aspect of the present disclosure.

### DETAILED DESCRIPTION

Advantages and features of the present disclosure, and a method of achieving the advantages and features will become apparent with reference to aspects described later in detail together with the accompanying drawings. However, the present disclosure is not limited to the aspects as disclosed under, but may be implemented in various different forms. Thus, these aspects are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various aspects are illustrated and described further below. It will be understood that the description herein is not intended to limit the claims to the specific aspects described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for describing aspects of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular aspects only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain aspect may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various aspects of the present disclosure may be partially or entirely combined with each other, and may be technically associated with each other or operate with each other. The aspects may be implemented independently of each other and may be implemented together in an association relationship.

In interpreting a numerical value, the value is interpreted as including a range unless there is no separate explicit description thereof.

It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various aspects of the present disclosure may be partially or entirely combined with each other, and may be technically associated with each other or operate with each other. The aspects may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments”, “examples”, “aspects”, and the like should not be construed such that any aspect or design as described is superior to or advantageous over other aspects or designs.

Further, the term “or” means “inclusive or” rather than “exclusive or”. That is, unless otherwise stated or clear from the context, the expression that “x uses a or b” means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for describing aspects.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

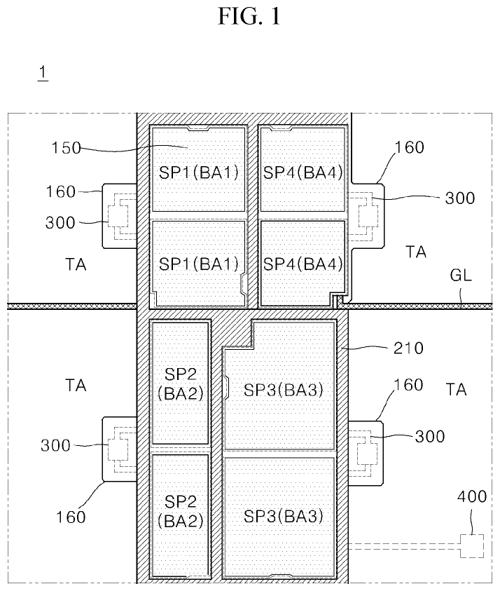

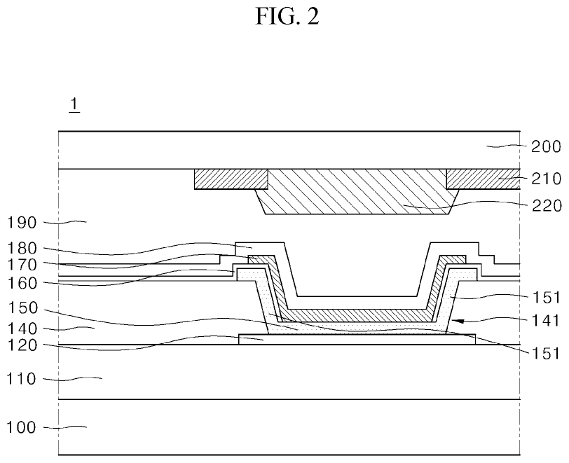

Hereinafter, a display device according to an aspect of the present disclosure will be described in detail with reference to FIG. 1 to FIG. 2.

In some aspects, a display device 1 may be an organic light-emitting diode display device is described below. However, the present disclosure is not limited thereto.

The display device 1 may include a display area and a non-display area surrounding the display area.

The display area may include a plurality of light-transmissive areas TA capable of transmitting external light therethrough and a plurality of light-emissive areas BA in which pixels emit light.

The light-transmissive area TA may be referred to as a transparent area.

A black matrix layer 210 may be disposed between the light-transmissive area TA and the light-emissive area BA.

The light-transmissive areas TA and the light-emissive areas BA may be alternately arranged with each other in a matrix form in each of a first direction and a second direction intersecting each other.

Therefore, the light-emissive area BA may be disposed between adjacent light-transmissive areas TA, while the light-transmissive area TA may be disposed between adjacent light-emissive areas BA.

The light-emissive area BA may correspond to one pixel and may include a plurality of sub-pixels constituting the pixel.

Hereinafter, an example in which one pixel is composed of a first sub-pixel SP1 that emits light of a first color, a second sub-pixel SP2 that emits light of a second color, a third sub-pixel SP3 that emits light of a third color, and a fourth sub-pixel SP4 which emits light of a fourth color will be described.

In this case, the first color may be red (R), the second color may be green (G), the third color may be blue (B), and the fourth color may be white (W). However, the present disclosure is not limited thereto.

Therefore, the light-emissive areas BA may include a first light-emissive area BA1 corresponding to the first sub-pixel SP1, a second light-emissive area BA2 corresponding to the second sub-pixel SP2, a third light-emissive area BA3 corresponding to the third sub-pixel SP3, and a fourth light-emissive area BA4 corresponding to the fourth sub-pixel SP4.

The first light-emissive area BA1, the second light-emissive area BA2, the third light-emissive area BA3, and the fourth light-emissive area BA4 may emit respectively light beams of the first color, the second color, the third color and the fourth color. However, the present disclosure is not limited thereto, and the first light-emissive area BA1, the second light-emissive area BA2, the third light-emissive area BA3, and the fourth light-emissive area BA4 may emit light of the same color, for example.

A color filter layer 220 may be disposed on each light-emissive area.

For example, a first color filter layer 220, a second color filter layer 220, a third color filter layer 220, and a fourth color filter layer 220 may be disposed on the first light-emissive area BA1, the second light-emissive area BA2, the third light-emissive area BA3, and the fourth light-emissive area BA4, respectively.

In this way, each sub-pixel may render a corresponding color via a combination of a pair of the light-emissive area BA and the color filter layer 220.

The display area may include a plurality of data lines (not shown) extending in the first direction and a plurality of gate lines GL extending in the second direction that intersects the first direction.

Each of areas corresponding to intersections of the data lines and the gate lines GL may correspond to one sub-pixel area SP1, SP2, SP3, or SP4.

According to an aspect of the present disclosure, a pair of the light-emissive areas emitting light of the same color may be disposed adjacent to each other.

Therefore, one light-emissive area BA may include a pair of the first light-emissive areas BA1 disposed adjacent to each other, a pair of the second light-emissive areas BA2 disposed adjacent to each other, and a pair of the third light-emissive areas BA3 disposed adjacent to each other, and a pair of the fourth light-emissive areas BA4 disposed adjacent to each other.

A branched structure 300 may be disposed in the light-transmissive area TA and electrically connects to the pair of light-emissive areas and emitting light of the same color that are disposed adjacent to each other.

For example, one end and the other end of one branched structure 300 may face the light-emissive area BA and be electrically connected to a pair of the first light-emissive areas BA1, respectively.

Similarly, one end and the other end of one branched structure 300 may face the light-emissive area BA and be electrically connected to a pair of the second light-emissive areas BA2, respectively. One end and the other end of one branched structure 300 may face the light-emissive area BA and be electrically connected to a pair of the third light-emissive areas BA3, respectively. One end and the other end of one branched structure 300 may face the light-emissive area BA and be electrically connected to a pair of the fourth light-emissive areas BA4, respectively.

When a defect occurs in a specific light-emissive area, the branched structure 300 electrically connected to the light-emissive area where the defect occurs may be altered such that the electrical connection to the defective light-emissive area is removed. In this way, a defective pixel may be repaired.

The branched structure 300 will be described later in additional detail.

A switching thin-film transistor, a driving thin-film transistor, a storage capacitor, and a light-emitting diode may be formed in each of the sub-pixels SP1, SP2, SP3, and SP4.

A gate electrode of the switching thin-film transistor may be connected to the gate line GL and a source electrode thereof may be connected to the data line.

A gate electrode of the driving thin-film transistor may be connected to a drain electrode of the switching thin-film transistor, and a source electrode of the driving thin-film transistor may be connected to a high-potential voltage VDD.

An anode electrode of the light-emitting diode is connected to a drain electrode of the driving thin-film transistor, and a cathode electrode thereof may be connected to a low-potential voltage VSS.

One side and the other side of the storage capacitor may be connected to the gate electrode and the drain electrode of the driving thin-film transistor, respectively.

The display device 1 including the sub-pixels SP1, SP2, SP3, and SP4 having the above circuit connection structure may display an image as follows.

The switching thin-film transistor is turned on according to the gate signal applied through the gate line GL. The data signal applied to the data line may be applied to the gate electrode of the driving thin-film transistor and one electrode of the storage capacitor through the switching thin-film transistor.

The driving thin-film transistor is turned on according to the data signal to control current flowing through the light-emitting diode to display an image.

The light-emitting diode may emit light based on a high-potential voltage (VDD) current transmitted through the driving thin-film transistor.

In the non-display area, a plurality of power lines and pads that supply various signals and power to the pixel may be disposed.

Each pixel P may be electrically connected to a high-potential voltage line (not shown) that applies the high-potential voltage VDD to a thin-film transistor, and a low-potential voltage line VSSL that applies the low-potential voltage VSS to the cathode electrode of the light-emitting diode.

A plurality of low-potential voltage lines VSSL for applying the low-potential voltage to the plurality of sub-pixels SP1, SP2, SP3, and SP4, respectively may be disposed in the display area AA.

For example, the plurality of low-potential voltage lines VSSL may extend in the first direction, which in the same direction as the plurality of data lines.

A low-potential voltage line VSSL may extend across a plurality of sub-pixels arranged in the first direction.

Accordingly, the plurality of sub-pixels arranged in the first direction may share the low-potential voltage line VSSL.

A low-potential voltage contact line 400 serves as a connection electrode that transfers the low-potential voltage VSS applied from the low-potential voltage line VSSL to the cathode electrode may be disposed in the light-transmissive area TA.

For example, one end of the low-potential voltage contact line 400 is electrically connected to the low-potential voltage line VSSL, while the other end thereof may be electrically connected to the cathode electrode.

The cathode electrode may be a common electrode disposed to cover a plurality of sub-pixels. Thus, the same low-potential voltage VSS may be applied to the remaining sub-pixels SP via the electrical connection between one low-potential voltage contact line 400 and one sub-pixel SP.

For example, as shown in FIG. 1, the low-potential voltage contact line 400 may be a line extending from the third sub-pixel SP3 toward the light-transmissive area TA. However, the present disclosure is not limited thereto.

The low-potential voltage contact line 400 will be further described later.

FIG. 2 is a cross-sectional view of a light-emissive area and a light-transmissive area corresponding to one sub-pixel of a display device according to an aspect of the present disclosure.

Hereinafter, the description is based on a single sub-pixel. However, this description may be equally applied to other sub-pixels unless otherwise stated.

Referring to FIG. 2, a first substrate 100 may be disposed.

The first substrate 100 may be referred to as a thin-film transistor substrate.

A buffer layer may be disposed on the first substrate 100.

For example, the buffer layer may be composed of a single layer or a multi-layer made of silicon oxide (SiOₓ) or silicon nitride (SiNₓ). However, the present disclosure is not limited thereto, and the buffer layer may be omitted.

A plurality of power lines, a plurality of data lines, a plurality of gate lines GL, a plurality of thin-film transistors, and a plurality of capacitors may be disposed on the buffer layer.

The thin-film transistor may act as a driving thin-film transistor or a switching thin-film transistor.

Each thin-film transistor may include an active layer, a gate electrode, a source electrode, and a drain electrode.

The active layer may be made of a semiconductor material such as an oxide semiconductor, amorphous silicon, or polysilicon.

An interlayer insulating layer may be disposed to electrically insulate the gate electrode, the source electrode, and the drain electrode from each other.

The interlayer insulating layer may be composed of a single layer or multiple layers made of silicon oxide (SiOₓ) or silicon nitride (SiNₓ). However, the present disclosure is not limited thereto.

The power line, the data line, and the gate line as described above may be disposed in the same layer. However, the present disclosure is not limited thereto, and the power line, the data line, and the gate line as described above may be disposed in different layers.

For example, the power line, the data line, and the gate line, and any one of the source electrode, the drain electrode, and the gate electrode of the thin-film transistor may be disposed in the same layer, may be made of the same material, and may be formed in the same process.

A first overcoat layer 110 may be formed on the interlayer insulating layer.

The first overcoat layer 110 may function as a first planarization layer.

Accordingly, the first overcoat layer 110 may be disposed to planarize a surface above the thin-film transistor.

The first overcoat layer 110 may include an organic material.

For example, the first overcoat layer 110 may be composed of a single layer or multiple layers made of polyimide or photo acryl. However, the present disclosure is not limited thereto.

A clad layer 120 may be disposed on the first overcoat layer 110.

The clad layer 120 may be formed with a transparent conductive material.

For example, the transparent conductive material may include at least one material selected from a group consisting of indium tin oxide (ITO), indium zinc oxide (IZO), and indium gallium zinc oxide (IGZO). However, the present disclosure is not limited thereto.

In some cases, the transparent conductive material as described above may have a very strong property that may resist a subsequent etching process that occurs after forming the clad layer 120.

Therefore, the clad layer 120 may function as a kind of an etch stopper.

Since the clad layer 120 may function as the etch stopper in this way, a surface roughness of a pixel electrode 150 formed on the clad layer 120 may be reduced.

If a subsequent process such as an etching process is performed when the clad layer 120 is not present under the pixel electrode 150, the first overcoat layer 110, which is weak against the etching, may be affected by the etching process and thus a surface roughness of the upper surface thereof may be increased.

When the pixel electrode 150 is formed on the first overcoat layer 110 having increased surface roughness, the pixel electrode 150 is affected by the increased surface roughness of the first overcoat layer 110 and the pixel electrode 150 may have increased surface roughness.

When the surface roughness of the pixel electrode 150 increases in this way, light efficiency may decrease.

However, according to the present disclosure, the clad layer 120 is formed under the pixel electrode 150 before the formation process of the pixel electrode 150. Thus, the surface of the pixel electrode may be modified so that the surface roughness of the pixel electrode formed on the transparent clad layer may be reduced, thereby improving the process stability.

The clad layer 120 is disposed in a position to correspond to the light-emissive area BA and may be disposed to contact a lower surface of the pixel electrode 150.

For example, the clad layer 120 may be formed in a pattern corresponding to a shape of the lower surface of the pixel electrode 150. An upper surface of the clad layer 120 may directly contact the lower surface of the pixel electrode 150.

A second overcoat layer 140 having an opening 141 defined therein may be formed on the clad layer 120.

The second overcoat layer 140 may function as a second planarization layer.

The second overcoat layer 140 may include an organic material.

For example, the second overcoat layer 140 may be composed of a single layer or multiple layers made of polyimide or photo acryl. However, the present disclosure is not limited thereto.

The opening 141 exposing at least a portion of an upper surface of the clad layer 120 may be formed in the second overcoat layer 140.

A plurality of openings 141 may be formed in the second overcoat layer 140 to correspond to the plurality of light-emissive areas BA, respectively.

For example, a lower surface of the opening 141 of the second overcoat layer 140 may be opened to expose the upper surface of the clad layer 120 except for an edge of the clad layer 120.

The upper surface of the clad layer 120 exposed through the opening 141 may substantially correspond to the light-emissive area BA.

A side surface of the opening 141 may be formed in an inclined manner to be inclined upwardly and outwardly.

For example, the opening 141 may be formed in a well shape. However, the present disclosure is not limited thereto.

The opening 141 of the second overcoat layer 140 may be formed in a dry etching process.

For example, the second overcoat layer 140 may be deposited and cured, and then the openings 141 may be formed therein in a dry etching process.

Since, in this way, the opening 141 is formed in the dry etching process that is advantageous in implementing a fine process, a more precise pattern of the opening 141 may be formed.

The opening 141 formed in the light-emissive area BA and in the second overcoat layer 140 and a contact hole or a contact formed in an area other than the light-emissive area BA and in the second overcoat layer 140 are connected to various lines or electrodes in the same dry etching process.

Therefore, according to an aspect of the present disclosure, as described above, the clad layer 120 serves as a kind of the etch stopper in the dry etching process. Thus, the surface of the pixel electrode 150 formed on the clad layer 120 may be modified to reduce surface roughness thereof, such that the process stability may be improved.

Therefore, when the opening 141 is formed in the dry etching process, the side surface of the opening 141 may be formed more precisely, and the lower surface of the opening 141 may be opened to expose the clad layer 120 such that a planarized upper surface of the clad layer 120 may be provided.

The pixel electrode 150 may be formed in the opening 141. The pixel electrode 150 may act as an anode electrode of the light-emitting diode.

Specifically, the pixel electrode 150 may be disposed on the clad layer 120, and the lower surface of the pixel electrode 150 may directly contact the upper surface of the clad layer 120.

As described above, the pixel electrode 150 may be formed on the planarized upper surface the clad layer 120, which has reduced surface roughness and causes the upper surface of the pixel electrode 150 to also be formed as a planarized surface with reduced surface roughness.

The pixel electrode 150 may include a non-planar reflective portion 151 extending along the side surface of the opening 141. In some aspects, the non-planar reflective portion may be configured to reflect light incident and may be referred to as a mirror portion.

That is, the pixel electrode 150 may be formed along a profile of the opening 141, and the non-planar reflective portion 151 may be formed along the side surface of the opening 141 as an inclined side surface.

An outer end of the pixel electrode 150 may extend from the non-planar portion 151 extending along the side surface of the opening 141 and along an upper surface of the second overcoat layer 140 by a predetermined distance.

A lower end of the non-planar reflective portion 151 may be disposed from the upper surface of the pixel electrode 150 disposed on the clad layer 120. A middle portion of the non-planar reflective portion 151 may extend along the inclined side surface of the opening 141 of the second overcoat layer 140. An upper end of the non-planar reflective portion 151 may be positioned on the second overcoat layer 140.

The pixel electrode 150 may include a metal material having excellent reflection efficiency so that light may be reflected therefrom to be directed in an upward direction as much as possible.

For example, the pixel electrode 150 may include silver (Ag) or APC (Ag; Pb; Cu), and may be composed of at least one or more layers. However, the present disclosure is not limited thereto.

Moreover, the pixel electrode 150 may include a transparent conductive material. The transparent conductive material may include at least one material selected from a group consisting of indium tin oxide (ITO), indium zinc oxide (IZO), and indium gallium zinc oxide (IGZO). However, the present disclosure is not limited thereto.

For example, the pixel electrode 150 may be formed to have a triple layers stack structure such as an ITO layer/an Ag alloy layer/an ITO layer.

The pixel electrode 150 may be made of a material with excellent reflection efficiency and thus may function as a reflective electrode capable of maximally reflecting the light from the light-emissive area having a top emission structure in an upward direction.

Therefore, according to an aspect of the present disclosure, the non-planar reflective portion 151 of the pixel electrode 150 extending along the side surface of the opening 141 may function as a side surface reflection mirror that is capable of reflecting light.

Specifically, the non-planar reflective portion 151 may be oriented in an inclined manner upwardly and inwardly of the light-emissive area BA such that light emitted from the lower surface of the pixel electrode 150 may be reflected upwardly and inwardly of the light-emissive area BA as much as possible.

In this way, the non-planar reflective portion 151 of the pixel electrode 150 acts as a side surface reflection mirror such that light loss in the light-emissive area BA may be reduced, and thus an amount of light emitted from the sub-pixel may be improved.

Moreover, the light reflected from the non-planar reflective portion 151 of the pixel electrode 150 is reflected upwardly and inwardly of the light-emissive area BA as much as possible. Thus, color mixing between light beams from adjacent sub-pixels emitting light beams of different colors may be reduced.

Therefore, according to an aspect of the present disclosure, the non-planar reflective portion 151 of the pixel electrode 150 extending along the side surface of the opening 141 acts as a side surface reflection mirror of light, such that light efficiency may be greatly improved.

A bank layer 160 may be formed on the second overcoat layer 140 and the pixel electrode 150 to expose at least a portion of the upper surface of the pixel electrode 150 overlapping the clad layer 120.

Specifically, the bank layer 160 may not cover the portion of the upper surface of the pixel electrode 150 to be exposed to an outside and may cover the non-planar reflective portion 151 of the pixel electrode 150.

Therefore, an end of the bank layer 160 may contact the upper surface of the pixel electrode 150.

The bank layer 160 may be an inorganic material layer including an inorganic material.

In this case, the inorganic material layer may be composed of a single layer or a multi-layer made of silicon oxide (SiOₓ) or silicon nitride (SiNₓ). However, the present disclosure is not limited thereto.

The portion of the upper surface of the pixel electrode 150 not covered with the bank layer 160 may be exposed and correspond to the light-emissive area BA from which light is emitted.

That is, a boundary between an inner end of the bank layer 160 and the upper surface of the pixel electrode 150 may also be a boundary of the light-emissive area BA.

In some cases, when the bank layer 160 includes an organic material layer having an organic material, a thickness of the bank layer 160 increases, and thus, a size of the light-emissive area BA may be reduced by the increased thickness, and the light-emissive area BA may be reduced.

That is, a portion of the upper surface of the pixel electrode 150 covered with the bank layer 160 may be a dead zone of the light-emissive area BA.

Moreover, an organic material formation process for forming the organic material layer has a larger process variation than that in an inorganic material formation process for forming the inorganic material layer. Thus, when considering the process error, the dead zone of the light-emissive area BA is further increased when the bank layer 160 is composed of the organic material layer.

According to an aspect of the present disclosure, the bank layer 160 formed on the pixel electrode 150 is made of an inorganic material. Thus, the bank layer 160 may be formed to have a thickness smaller and the process error may be reduced, compared to those when the bank layer is made of the organic material.

Therefore, according to an aspect of the present disclosure, a width in a left-right direction of the dead zone of the light-emissive area BA formed on the pixel electrode 150 may be reduced, such that the light efficiency of the display device may be improved.

An organic light-emissive layer 170 may be disposed on the pixel electrode 150.

The organic light-emissive layers 170 disposed in a position corresponding to the light-emissive areas BA and emitting light of different colors may be spaced apart from each other to emit light of different colors.

For example, the organic light-emissive layers 170 may include light-emissive layers EML emitting red, green, and blue light beams, respectively. The light-emissive layer may be made of a phosphorescent material or a fluorescent material. A specific example thereof is not particularly limited.

The organic light-emissive layers 170 may respectively include the light-emissive layers that emit white light.

A hole injection layer HIL and/or a hole transporting layer HTL may be additionally disposed between the pixel electrode 150 and the light-emissive layer EML. An electron transporting layer ETL and/or an electron injection layer HIL may be additionally disposed between the light-emissive layer EML and the common electrode 180.

The common electrode 180 may be formed on the organic light-emissive layer 170 to cover a plurality of sub-pixels.

The common electrode 180 may act as a cathode electrode of the light-emitting diode.

The common electrode 180 may include a transparent conductive material so that light reflected from the pixel electrode 150 may transmit through the common electrode 180 and travel upwardly. For example, the transparent conductive material may include at least one material selected from a group consisting of indium tin oxide (ITO), indium zinc oxide (IZO), and indium gallium zinc oxide (IGZO). However, the present disclosure is not limited thereto.

An area where the pixel electrode 150, the organic light-emissive layer 170, and the common electrode 180 are stacked to overlap each other in a vertical direction corresponds to the light-emissive area BA in which light is emitted.

A second substrate 200 may be disposed on the common electrode 180.

The second substrate 200 may be a color filter substrate on which a black matrix layer 210 and a color filter layer 220 are formed.

The black matrix layer 210 forms a boundary between adjacent the plurality of light-emissive areas BA and a boundary between the light-emissive area BA, and the light-transmissive area TA may be formed on the second substrate 200.

The black matrix layer 210 may serve to block light incident to the boundary.

The color filter layer 220 may be formed on the second substrate 200, and the color filter layer 220 may be disposed between adjacent black matrix layers 210.

Specifically, an edge of the color filter layer 220 may be disposed to overlap the black matrix layer 210.

That is, the color filter layer 220 and the black matrix layer 210 may be formed in the same layer on the second substrate 200, while the edge of the color filter layer 220 may be formed on the black matrix layer 210 to overlap the black matrix layer 210.

The color filter substrate including the second substrate 200 and the black matrix layer 210 and the color filter layer 220 formed on the second substrate 200 as described above may be bonded to the thin-film transistor substrate.

That is, the color filter substrate may be disposed to face the thin-film transistor substrate and may be bonded and fixed to the thin-film transistor substrate via an adhesive layer 190.

Accordingly, the adhesive layer 190 may be disposed on the organic light-emissive layer 170 in a state in which the color filter substrate and the thin-film transistor substrate are bonded to each other.

The color filter layer 220 is spaced from and disposed on the pixel electrode 150 to overlap with the opening 141, and the black matrix layer 210 is disposed to partially overlap with the edge of the color filter layer 220 and may be disposed on the adhesive layer 190.

The second substrate 200 may be formed on the color filter layer 220 and the black matrix layer 210 to support the color filter layer 220 and the black matrix layer 210 thereon.

The color filter layer 220 may be disposed to overlap the light-emissive area BA in the vertical direction and may have a color corresponding to a color to be rendered by each sub-pixel.

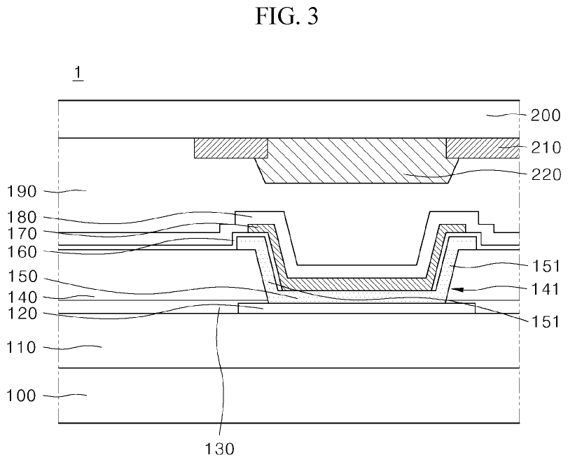

Referring to FIG. 3, in the display device 1, according to another aspect of the present disclosure, a passivation layer 130 may be additionally formed between the first overcoat layer 110 and the second overcoat layer 140.

The passivation layer 130 may be composed of a single layer or multiple layers made of silicon oxide (SiOₓ) or silicon nitride (SiNₓ). However, the present disclosure is not limited thereto.

The passivation layer 130 disposed on the first overcoat layer 110 may be formed on the clad layer 120 to overlap an edge of the clad layer 120.

That is, the passivation layer 130 and the clad layer 120 may be disposed in the same layer on the first overcoat layer 110, while a portion of the passivation layer 130 may be formed on the clad layer 120 to overlap the edge of the clad layer 120.

The passivation layer 130 and the second overcoat layer 140 may share the opening 141.

For example, after the clad layer 120 is formed on the first overcoat layer 110, the passivation layer 130 and the second overcoat layer 140 may be deposited to cover the clad layer 120.

The deposited passivation layer 130 and second overcoat layer 140 may be cured, and the second overcoat layer 140 and the passivation layer 130 may be sequentially etched in a dry etching process to form the opening 141.

Since the second overcoat layer 140 and the passivation layer 130 are etched in the same etching process, the second overcoat layer 140 and the passivation layer 130 may share one opening 141 formed in the same etching process.

In this case, the opening 141 may be formed in the light-emissive area BA and in the second overcoat layer 140 and a contact hole or a contact may be formed in an area other than the light-emissive area BA and in the second overcoat layer 140. The contact hole or the contact may be connected to various lines or electrodes and may be formed based on a photolithography process using an exposure process and a development process.

The black matrix layer 210 as described above may constitute the boundary between the light-transmissive area TA and the light-emissive area BA and the boundary between light-emissive areas BA adjacent to each other and may reduce the color mixing from adjacent pixels and sub-pixels. However, as the width in the left-right direction of the black matrix layer 210 increases, both the transmittance in the light-transmissive area TA and the aperture ratio in the light-emissive area BA may decrease.

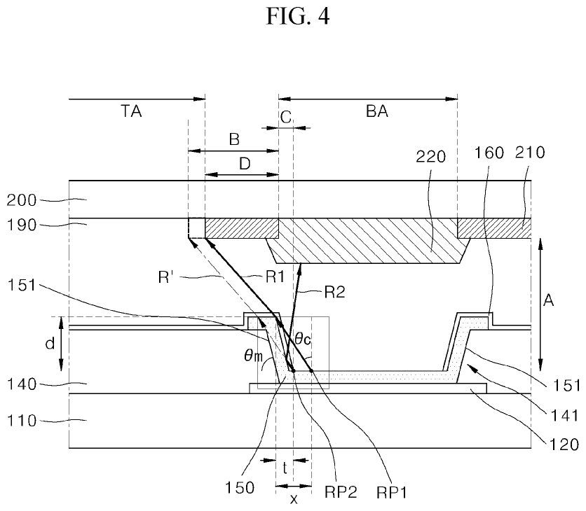

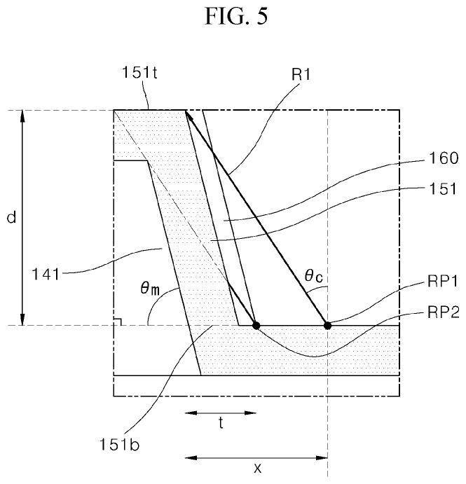

Therefore, hereinafter, a formula for calculating a minimum width in the left-right direction of the black matrix layer 210 will be described in detail with reference to FIGS. 4 and 5. In some aspects, the minimum width may prevent the color mixing while improving both the transmittance and the aperture ratio.

The minimum width D in the left-right direction of the black matrix layer 210 may be determined based on a following Equation 1:

$$D = B - ( x - t ) \qquad ( Equation 1 )$$

In the above Equation 1, B may mean a minimum width in the left-right direction of the black matrix layer 210 which blocks a portion of the virtual light R′ not totally reflected from the second substrate 200 of virtual light R′ emitted from the upper surface of the pixel electrode 150 and then passing through the non-planar reflective portion 151.

As used herein, the virtual light R′ may be reflected light R2 reflected from the non-planar reflective portion 151 that is directed inwardly and upwardly. However, when it is assumed that the pixel electrode 150 is free of the non-planar reflective portion 151, the virtual light R′ may be any light emitted toward a position at which the non-planar reflective portion 151 is disposed.

Therefore, the virtual light R′ as described above further travels in a direction in which the light is emitted, and then reaches the second substrate 200. In this case, depending on an angle of the direction in which the light is emitted, a portion of the light may undergo total reflection and return in a downward direction, while the other portion of the light may pass through the light-transmissive area TA and be emitted to the outside.

Therefore, the minimum width in the left-right direction of the black matrix layer 210 may be the minimum width in the left-right direction of the black matrix layer 210 required to block the virtual light R′ that is reflected from the second substrate 200.

If the pixel electrode 150 is does not include the non-planar reflective portion 151, the width in the left-right direction of the black matrix layer 210 may be determined based on the minimum width B in the left-right direction of the black matrix layer 210.

However, according to the aspect of the present disclosure, the non-planar reflective portion 151 of the pixel electrode 150 may reflect a portion of light that does not satisfy the reflection requirement. Thus, the width in the left-right direction of the black matrix layer 210 may be reduced.

According to an aspect of the present disclosure, a reduction amount in the width in the left-right direction of the black matrix layer 210 may be calculated more precisely to improve the transmittance and the aperture ratio more effectively and to the maximum extent.

For example, the minimum width D in the left-right direction of the black matrix layer 210 as used in the present disclosure may be determined in consideration of a boundary between the light-emissive area BA and the light-transmissive area TA at which light emitted from one light-emissive area BA starts to be reflected in a neighboring light-transmissive area TA. The minimum width D may also be in consideration of a boundary between light-emissive areas BA capable of minimizing an amount at which the light emitted from one light-emissive area BA is emitted to the color filter layer 220 corresponding to another neighboring light-emissive area BA.

The minimum width B in the left-right direction of the black matrix layer 210 may be determined based on a following Equation 2:

$$B = A \cdot tan {θ}_{c} - C \qquad ( Equation 2 )$$

In the above Equation 2, A may denote a height from a portion of the upper surface of the pixel electrode 150 not covered with the bank layer 160 to be exposed to a lower surface of the black matrix layer 210.

C may denote a width in the left-right direction between an inner boundary of the black matrix layer 210 and a second light source point RP2 located at a boundary of the portion of the upper surface of the pixel electrode 150 not covered with the bank layer 160 to be exposed.

In this case, the inner boundary of the black matrix layer 210 corresponds to a boundary between the black matrix layer 210 and the color filter layer 220.

For example, the inner boundary of the black matrix layer 210 may correspond to a boundary between the black matrix layer 210 and the color filter layer 220 disposed in the same layer on the second substrate 200.

Moreover, the boundary of the portion of the upper surface of the pixel electrode 150 not covered with the bank layer 160 to be exposed may correspond to a boundary between the bank layer 160 and the pixel electrode 150.

In this case, the second light source point RP2 may refer to an outermost point of the light-emissive area BA where light may be emitted.

In some aspects, angle

$${θ}_{c} = {sin}^{- 1} \frac{{n}_{1}}{{n}_{2}} ,$$

with n₁ being a refractive index of air, and n₂ being a refractive index of the second substrate.

To derive a more accurate measurement of the refractive index, the material of the adhesive layer 190 through which light emitted from the pixel electrode 150 passes may be selected such that the refractive index of the material of the adhesive layer 190 may be substantially the same as the refractive index n₂ of the second substrate 200.

Angle θ_{c} measured as described above may corresponds to a critical angle at which light emitted from the pixel electrode 150 is totally reflected from the second substrate 200.

Therefore, when an angle between a direction normal to the upper surface of the pixel electrode 150 and a direction at which light is output from the upper surface of the pixel electrode 150 is greater than the total reflection critical angle θ_{c}, the light may be totally reflected from the second substrate 200.

On the contrary, when an angle between a direction normal to the upper surface of the pixel electrode 150 and a direction at which light is output from the upper surface of the pixel electrode 150 is smaller than the total reflection critical angle θ_{c}, the light may be blocked by the black matrix layer 210 or may be emitted to the outside through the color filter layer 220.

In one example, x−t corresponds to the width in the left-right direction of the black matrix layer 210 that may be additionally reduced and may be determined based on values of x and t calculated as follows.

Specifically, x−t may be determined based on a following Equation 3:

$$x - t = \frac{d}{cos {θ}_{c}} \cdot sin {θ}_{c} - \frac{d}{tan {θ}_{m}} \qquad ( Equation 3 )$$

In this Equation 3, x may be a width in the left-right direction between an inner side of an upper end 151t of the non-planar reflective portion 151 and a first light source point RP1 which is disposed on the upper surface of the pixel electrode 150 and from which blocked light R1 which is to be blocked by the black matrix layer 210 is emitted.

In this case, the blocked light R1 emitted from the first light source point RP1 and blocked by the black matrix layer 210 may be present on the boundary on which light not blocked by the black matrix layer 210 but propagating to the second substrate 200 is present.

In the above Equation 3, t may be a width in the left-right direction between the inner side of the upper end 151t of the non-planar reflective portion 151 and the second light source point RP2 located at a boundary of the portion of the upper surface of the pixel electrode 150 not covered with the bank layer 160 to be exposed.

In the above Equation 3, d may be a height from the upper end 151t of the non-planar reflective portion 151 to a lower end 151b of the non-planar reflective portion 151.

In the above Equation 3, inclination angle θₘ may be an inclination angle of the non-planar reflective portion 151 measured in a direction toward the opening 141.

Since the non-planar reflective portion 151 is inclined in a direction toward the color filter layer 220, the inclination angle θₘ of the non-planar reflective portion 151 may be an acute angle.

As described above, according to an aspect of the present disclosure, with considering the total reflection angle of light emitted from the upper surface of the pixel electrode 150 and various factors related to the non-planar reflective portion 151 of the pixel electrode 150, the minimum width D in the left-right direction of the black matrix layer 210 constituting the boundary between the light-transmissive area TA and the light-emissive area BA and the boundary between adjacent light-emissive areas BA may be calculated.

The minimum width D in the left-right directions of the black matrix layer 210 may be calculated and then may be used to reduce the dead zone of the light-emissive area BA formed in the light-transmissive area TA and the color filter layer 220 due to the black matrix layer 210. Thus, both the transmittance and the aperture ratio may be improved.

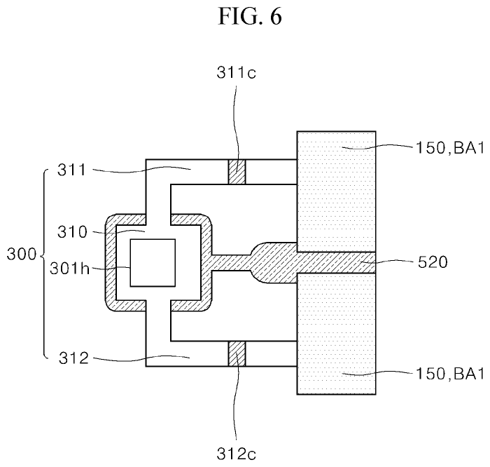

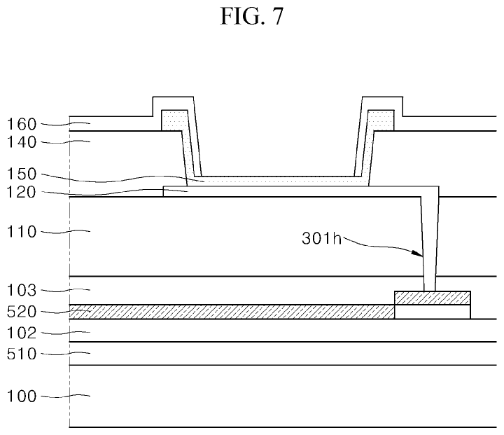

FIG. 6 is a plan view of a branched structure of a display device according to an aspect of the present disclosure. FIG. 7 is a cross-sectional view of the branched structure connected to the light-emissive area.

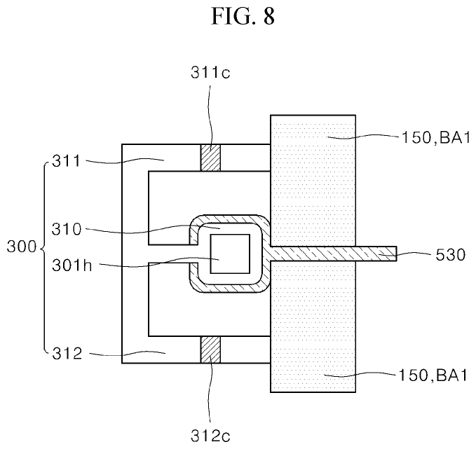

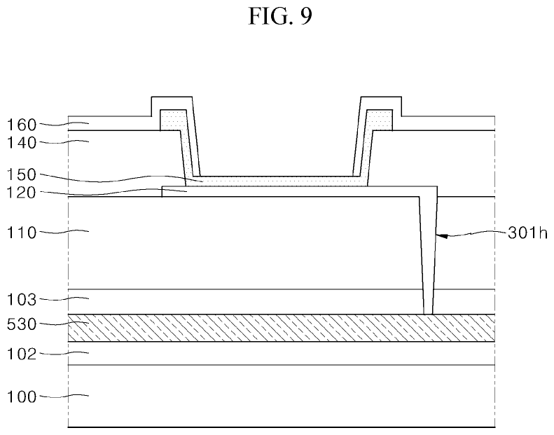

Moreover, FIG. 8 is a plan view of a branched structure of a display device according to another aspect of the present disclosure. FIG. 9 is a cross-sectional view of the branched structure connected to the light-emissive area.

The branched structure 300 as described above may have at least a partial area disposed in the light-transmissive area TA. One end and the other end of each branched structure 300 may be respectively electrically connected to a pair of light-emissive areas BA emitting light of the same color and adjacent to each other.

In one example, a plurality of capacitors may be disposed in the light-emissive area BA. The plurality of capacitors may include a capacitor including a first capacitor electrode 510 and a second capacitor electrode 520, and a capacitor including the second capacitor electrode 520 and a third capacitor electrode 530.

The first capacitor electrode 510 and the light blocking layer may be made of the same material and may be disposed in the same layer. The second capacitor electrode 520 and the active layer may be made of the same material and may be disposed in the same layer. The third capacitor electrode 530 and the gate electrode may be made of the same material and may be disposed in the same layer.

In this case, the second capacitor electrode 520 may be made of an oxide semiconductor such as IZO or IGZO, and a material such as IGZO may be converted into a conductor using a plasma process.

The buffer layer 102 may be disposed between the first capacitor electrode 510 and the second capacitor electrode 520. The gate insulating layer may be disposed between the second capacitor electrode 520 and the third capacitor electrode 530.

The branched structure 300 may include a branched contact 310 connected to the capacitor electrode located in the light-emissive area BA, and a first extension 311 and a second extension 312 extending from one side and the other side of the branched contact 310, respectively to be electrically connected to a pair of light-emissive areas BA1.

Referring to FIGS. 6 and 7, the branched contact 310 of the branched structure 300 may be electrically connected to the second capacitor electrode 520 constituting the capacitor via a branched contact hole 301h.

At least a partial area of the second capacitor electrode 520, which is made of the same material as the active layer made of an oxide semiconductor material, may be converted to be conductive.

For example, a partial area thereof electrically connected to the clad layer 120 and an area thereof extending in one direction from the partial area may be converted to be conductive.

In this case, the conductive pattern is not particularly limited. It may suffice that the second capacitor electrode 520 is converted to be conductive to have electrical conductivity.

Referring to FIG. 8 and FIG. 9, in another aspect, the branched contact 310 of the branched structure 300 may be electrically connected to the third capacitor electrode 530 constituting the capacitor via the branched contact hole 301h.

The first extension 311 and the second extension 312 may be electrically connected to the pixel electrodes 150 of the light-emissive areas BA1, respectively.

The branched structure 300 may extend from the clad layer 120.

Therefore, the branched structure 300 may include a transparent conductive material.

For example, the transparent conductive material may include at least one material selected from a group consisting of indium tin oxide (ITO), indium zinc oxide (IZO), and indium gallium zinc oxide (IGZO). However, the present disclosure is not limited thereto.

The first extension 311 and the second extension 312 may include a first repair cutting area 311c and a second repair cutting area 312c as predetermined partial areas thereof respectively.

An additional clad layer may be disposed in the first repair cutting area 311c and the second repair cutting area 312c, and the additional clad layer may include molybdenum titanium (MoTi).

Accordingly, the first repair cutting area 311c and the second repair cutting area 312c may be composed of a double layer including the clad layer 120 made of the transparent conductive material and the additional clad layer including MoTi.

In this way, the additional clad layer including MoTi may be additionally disposed in each of the first repair cutting area 311c and the second repair cutting area 312c to improve cutting stability in each of the first repair cutting area 311c and the second repair cutting area 312c to improve repairing of the defective pixel.

For example, a laser having a wavelength of 532 nm or 1064 nm may be used for the repair cutting.

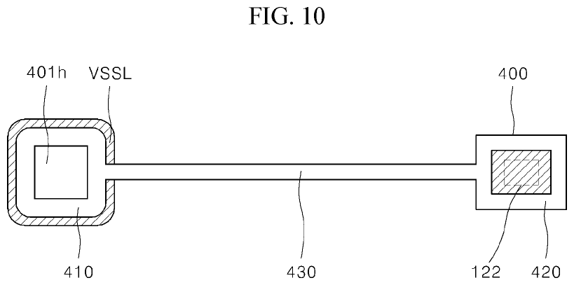

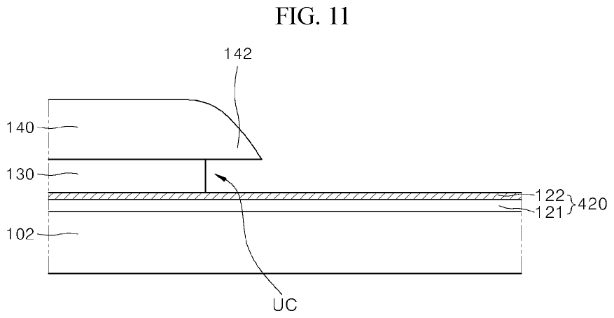

FIG. 10 is a plan view of a low-potential voltage contact line of a display device according to an aspect of the present disclosure. FIG. 11 is a cross-sectional view of the low-potential voltage contact line connected to the light-emissive area.

A low-potential voltage contact line 400 may have at least a partial area disposed in the light-transmissive area TA and may apply a low-potential (VSS) voltage to the light-emissive area BA.

The low-potential voltage contact line 400 may include a first line contact 410 electrically connected to the low-potential voltage line VSSL, a second line contact 420 electrically connected to the light-emissive area BA, and a line connection portion 430 extending to connect the first line contact 410 and the second line contact 420 to each other.

The first line contact 410 may be electrically connected to the low-potential voltage line VSSL through contact hole 401h.

In this case, at least a partial area of each of the second line contact 420 and the line connection portion 430 may be disposed in the light-transmissive area TA.

The low-potential voltage contact line 400 may extend from the clad layer 120 and may include a transparent conductive material.

For example, the transparent conductive material may include at least one material selected from a group consisting of indium tin oxide (ITO), indium zinc oxide (IZO), and indium gallium zinc oxide (IGZO). However, the present disclosure is not limited thereto.

An additional clad layer may be disposed in the second line contact 420, and the additional clad layer may include MoTi.

Specifically, the passivation layer 130 may be disposed on the second line contact 420. The second overcoat layer 140 may include an overhang 142 disposed on the passivation layer 130 such that an undercut UC may be formed under the overhang 142.

In the undercut UC, the second line contact 420 may be electrically connected to the light-emissive area BA.

The second line contact 420 may be composed of a double layer including a first clad layer 121 and a second clad layer 122.

In this case, the first clad layer 121 may be made of a transparent conductive material, while the second clad layer 122 may be made of MoTi.

In this way, in the undercut UC, the second line contact 420 is composed of the double layer including MoTi. Stability against a buffered oxide etchant (BOE) etching solution for etching a silicon oxide film may be improved.

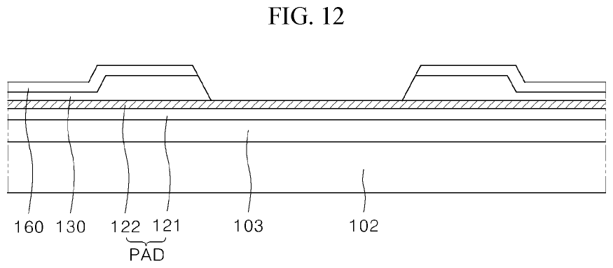

FIG. 12 is a cross-sectional view of a pad of a display device according to an aspect of the present disclosure.

A pad PAD may be composed of a double layer of the first clad layer 121 and the second clad layer 122 and may be disposed on the buffer layer 102 and the interlayer insulating layer 103. A surface of the pad not covered with the passivation layer 130 and the bank layer 160 disposed thereon may be a pad electrode.

In this case, the first clad layer 121 may be made of a transparent conductive material, and the second clad layer 122 may be made of MoTi.

In this way, the pad PAD is composed of the double layer including MoTi. Thus, the stability against a BOE etching solution that etches a silicon oxide film may be increased.

According to an aspect of the present disclosure described as above, at least a partial area of each of the branched structure 300 and the low-potential voltage contact line 400 disposed in the light-transmissive area TA is composed of the transparent clad layer 120. Thus, fine diffraction that may occur due to non-transparent fine patterns may be minimized.

Therefore, according to an aspect of the present disclosure, visibility in the light-transmissive area TA may be improved and reflectivity in the light-transmissive area TA may be reduced.

A display device according to an aspect of the present disclosure described above may be described as follows.

One aspect of the present disclosure provides a display device comprising: a first substrate; a pixel electrode including a non-planar reflective portion extending along a side surface of an opening disposed in a light-emissive area on the first substrate; a bank layer covering the mirror portion and exposing an upper surface of the pixel electrode to be exposed; a color filter layer disposed on the pixel electrode and spaced apart from the pixel electrode; a black matrix layer disposed to partially overlap an edge of the color filter layer; and a second substrate disposed opposite to the first substrate, wherein the color filter layer and the black matrix layer are disposed on the second substrate,

wherein a minimum width D in a left-right direction of the black matrix layer is determined based on a Equation 1 as noted above. In some aspects, as noted in the above Equation 1, B denotes a minimum width in the left-right direction of the black matrix layer blocking virtual light beams not totally reflected from the second substrate among virtual light beams emitted from the upper surface of the pixel electrode and then passing through the mirror portion.

Further, in the above Equation 1, x denotes a width in the left-right direction between an inner side of an upper end of the mirror portion and a first light source point positioned on the upper surface of the pixel electrode, wherein light to be blocked by the black matrix layer is emitted from the first light source point,

wherein in the above Equation 1, t denotes a width in the left-right direction between the inner side of the upper end of the mirror portion and a second light source point positioned at a boundary of the upper surface of the pixel electrode not covered with the bank layer to be exposed.

In some implementations of the present disclosure, B is determined based on Equation 2 as noted above. For example, in the above Equation 2, A denotes a height from the upper surface of the pixel electrode not covered with the bank layer to be exposed to a lower surface of the black matrix layer, C denotes a width in the left-right direction between an inner boundary of the black matrix layer and the second light source point RP2, and

$${θ}_{c} = {sin}^{- 1} \frac{{n}_{1}}{{n}_{2}} ,$$

where n₁ is a refractive index of air, and n₂ is a refractive index of the second substrate.

In some aspects of the present disclosure, when an angle between a direction normal to the upper surface of the pixel electrode and a direction at which light is output from the upper surface of the pixel electrode is greater than θ_{c}, the light is totally reflected from the second substrate, wherein the angle between the direction normal to the upper surface of the pixel electrode and the direction at which light is output from the upper surface of the pixel electrode is smaller than θ_{c}, and the light is blocked by the black matrix layer or is emitted to an outside through the color filter layer.

In some implementations of the present disclosure, x−t is determined based on Equation 3 above. As noted in the above Equation 3, d denotes a height from a top of the mirror portion to a bottom of the mirror portion, and θₘ denotes an inclination angle of the mirror portion measured in a direction toward the opening.

In some implementations of the present disclosure, a first overcoat layer and a transparent clad layer are disposed between the first substrate and the pixel electrode, wherein the first overcoat layer is disposed on the first substrate, wherein the transparent clad layer is disposed on the first overcoat layer.

In some implementations of the present disclosure, a second overcoat layer is disposed on the clad layer, wherein the second overcoat layer has the opening defined therein exposing at least a portion of an upper surface of the clad layer.

In some implementations of the present disclosure, the bank layer is disposed on the second overcoat layer and the pixel electrode so as not to cover at least a portion of the upper surface of the pixel electrode overlapping the clad layer to be exposed.

In some implementations of the present disclosure, the light-emissive area includes a plurality of light-emissive areas, wherein the display device further comprises a plurality of light-transmissive areas, wherein the black matrix layer constitutes a boundary between adjacent ones of the plurality of the light-emissive areas and constitutes a boundary between the light-emissive area and the light-transmissive area.

In some implementations of the present disclosure, an upper surface of the clad layer is planarized, wherein the pixel electrode is in direct contact with the clad layer.

In some implementations of the present disclosure, each of the first overcoat layer and the second overcoat layer includes an organic material, wherein the bank layer includes an inorganic material.

In some implementations of the present disclosure, a passivation layer including an inorganic material is disposed between the first overcoat layer and the second overcoat layer, wherein the passivation layer is disposed on the clad layer to partially overlap an edge of the clad layer, wherein the passivation layer and the second overcoat layer share the opening with each other.

In some implementations of the present disclosure, the light-emissive area includes a plurality of light-emissive areas, wherein the display device further comprises: a plurality of light-transmissive areas; and a branched structure having at least a partial area disposed in the light-transmissive area, wherein one end and the other end of the branched structure are respectively electrically connected to a pair of the light-emissive areas emitting color of the same color and adjacent to each other, wherein the branched structure extends from the clad layer and includes a transparent conductive material.

In some implementations of the present disclosure, the branched structure includes: a branched contact connected to a capacitor electrode; and a first extension and a second extension respectively extending from one side and the other side of the branched contact and respectively electrically connected to the pair of light-emissive areas, wherein the first extension and the second extension include a first repair cutting area and a second repair cutting area, respectively, wherein an additional clad layer is disposed in each of the first repair cutting area and the second repair cutting area.

In some implementations of the present disclosure, the light-emissive area includes a plurality of light-emissive areas, wherein the display device further comprises: a plurality of light-transmissive areas; and a low-potential voltage contact line having at least a partial area disposed in the light-transmissive area, wherein the low-potential voltage contact line applies a low-potential voltage to the light-emissive area, wherein the low-potential voltage contact line includes: a first line contact electrically connected to a low-potential voltage line; a second line contact electrically connected to the light-emissive area; and a line connection portion connecting the first line contact and the second line contact to each other, wherein the low-potential voltage contact line extends from the clad layer, and includes a transparent conductive material.

In some implementations of the present disclosure, an additional clad layer is disposed in the second line contact.

In some implementations of the present disclosure, the clad layer includes a transparent conductive material, wherein the transparent conductive material includes at least one material selected from a group consisting of indium tin oxide (ITO), indium zinc oxide (IZO), and indium gallium zinc oxide (IGZO).

In some implementations of the present disclosure, the additional clad layer includes MoTi.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A display device comprising:
a first substrate;
a pixel electrode including a reflective portion extending along a tapered side surface of an opening disposed in a light-emissive area on the first substrate, wherein an angle of the tapered side surface is associated with the opening of the light-emissive area;
a bank layer covering the reflective portion and exposing an upper surface of the pixel electrode;
a color filter layer disposed on the pixel electrode and spaced apart from the pixel electrode;
a black matrix layer disposed to partially overlap an edge of the color filter layer; and
a second substrate disposed opposite to the first substrate, wherein the color filter layer and the black matrix layer are disposed on the second substrate,
wherein a width in a horizontal direction of the black matrix layer is determined based on a depth of the pixel electrode associated with the tapered side surface and a height of the black matrix layer with respect to the pixel electrode.

2. The display device of claim 1, wherein the width of the black matrix layer is inversely proportional to the depth of the pixel electrode associated with the tapered side surface, and
wherein the width of the black matrix layer is proportional to the height of the black matrix layer with respect to the pixel electrode.

3. The display device of claim 2, wherein when an angle between a direction normal to the upper surface of the pixel electrode and a direction at which light is output from the upper surface of the pixel electrode is greater than a first threshold, the light is totally reflected from the second substrate,
wherein the angle between the direction normal to the upper surface of the pixel electrode and the direction at which light is output from the upper surface of the pixel electrode is smaller than the first threshold, and the light is blocked by the black matrix layer or is emitted to an outside through the color filter layer.

4. The display device of claim 1, wherein the light-emissive area includes a plurality of light-emissive areas,
wherein the display device further comprises a plurality of light-transmissive areas,
wherein the black matrix layer forms a boundary between adjacent light-emissive areas and forms a boundary between the light-emissive area and a light-transmissive area.

5. The display device of claim 1, wherein a first overcoat layer and a clad layer are disposed between the first substrate and the pixel electrode,
wherein the first overcoat layer is disposed on the first substrate,
wherein the clad layer is transparent and is disposed on the first overcoat layer.

6. The display device of claim 5, wherein a second overcoat layer is disposed on the clad layer, wherein the second overcoat layer has the opening defined therein exposing at least a portion of an upper surface of the clad layer.

7. The display device of claim 6, wherein the bank layer is disposed on the second overcoat layer and a portion of the pixel electrode, wherein the bank layer does not cover at least a portion of the upper surface of the pixel electrode overlapping the clad layer.

8. The display device of claim 6, wherein each of the first overcoat layer and the second overcoat layer includes an organic material,
wherein the bank layer covering the tapered side surface of the pixel electrode includes an inorganic material.

9. The display device of claim 6, wherein a passivation layer including an inorganic material is disposed between the first overcoat layer and the second overcoat layer,
wherein the passivation layer is disposed on the clad layer so as to partially overlap an edge of the clad layer,
wherein the passivation layer and the second overcoat layer share the opening with each other.

10. The display device of claim 6, wherein the upper surface of the clad layer is planarized,
wherein the pixel electrode is in direct contact with the clad layer.

11. The display device of claim 6, wherein the light-emissive area includes a plurality of light-emissive areas,
wherein the display device further comprises:
a plurality of light-transmissive areas; and
a transparent conductive structure having disposed in a light-transmissive area, wherein the transparent conductive structure are electrically connected to a pair of the light-emissive areas emitting color of the same color and adjacent to each other,
wherein the transparent conductive structure is connected to a first clad portion and a second clad portion from the clad layer, wherein the first clad portion and the second clad portion are separated.

12. The display device of claim 11, wherein the transparent conductive structure includes:
a contact connected to a capacitor electrode; and
a first extension and a second extension respectively extending from one side and the other side of the contact and respectively electrically connected to the pair of light-emissive areas,
wherein the first extension and the second extension include a first repair cutting area and a second repair cutting area, respectively,
wherein an additional clad layer is disposed in each of the first repair cutting area and the second repair cutting area.

13. The display device of claim 6, wherein the light-emissive area includes a plurality of light-emissive areas,
wherein the display device further comprises:
a plurality of light-transmissive areas; and
a low-potential voltage line having disposed in a light-transmissive area, wherein the low-potential voltage line applies a low-potential voltage to the light-emissive area,
wherein the low-potential voltage line includes:
a first contact electrically connected to the low-potential voltage line;
a second contact electrically connected to the light-emissive area; and
a line connection portion connecting the first contact and the second contact to each other,
wherein the low-potential voltage line extends from the clad layer and includes a transparent conductive material.

14. The display device of claim 13, wherein an additional clad layer is disposed in the second contact.

15. The display device of claim 14, wherein the additional clad layer includes molybdenum titanium (MoTi).

16. The display device of claim 13, wherein the low-potential voltage line, a transparent conductive structure electrically connected to a pair of light-emissive areas emitting color of the same color, and the clad layer are disposed in a light transmissive area and are formed during a single process step.

17. The display device of claim 6, wherein the clad layer includes a transparent conductive material,
wherein the transparent conductive material includes at least one material selected from a group consisting of indium tin oxide (ITO), indium zinc oxide (IZO), and indium gallium zinc oxide (IGZO).

18. A display device comprising:
a first substrate;
an electrode configured to emit light, the electrode including a planar portion and a non-planar portion configured to reflect light;
a bank layer covering the non-planar portion of the electrode;
a color filter disposed over the electrode;
a black matrix layer disposed adjacent to an edge of the color filter layer; and
a second substrate disposed opposite to the first substrate, wherein the color filter and the black matrix layer are disposed on the second substrate,
wherein a width of the black matrix layer is based on an angle of light emitted from the electrode and an inner edge of the black matrix layer, and
wherein the non-planar portion of the electrode is configured to reflect light from the color filter.

19. The display device of claim 18, wherein an inner surface of the non-planar portion corresponds to an edge of the color filter and an edge of the black matrix layer.

20. The display device of claim 18, wherein the bank layer comprises an inorganic material to increase an exposure size of a planar portion of the electrode.

21. The display device of claim 20, wherein a reduced thickness of the inorganic material reduces a dead zone of a light-emissive area of the electrode.

22. The display device of claim 18, wherein a thickness of the bank layer is less than a thickness of the than an overcoat layer.
